(19) United States
(12) Patent Application Publication
(10) Pub. No.: US 2020/0227552 A1
(43) Pub. Date: Jul. 16, 2020

(54) SEMICONDUCTOR DEVICE WITH DIELECTRIC NECK SUPPORT AND METHOD FOR MANUFACTURING THE SAME

(71) Applicant: Vanguard International Semiconductor Corporation, Hsinchu (TW)

(72) Inventors: Chih-Wei LIN, Jhubei City (TW); Pao-Hao CHIU, Kaohsiung City (TW)

(73) Assignee: Vanguard International Semiconductor Corporation, Hsinchu (TW)

(21) Appl. No.: 16/246,087

(22) Filed: Jan. 11, 2019

(51) Int. Cl. H01L 29/78; H01L 29/10; H01L 29/423; H01L 29/08; H01L 29/40; H01L 29/66; H01L 21/28

(52) U.S. Cl. CPC H01L 29/7816; H01L 29/1095; H01L 29/42376; H01L 29/0865; H01L 29/42364; H01L 29/0653; H01L 29/401; H01L 29/66681; H01L 29/0882; H01L 21/28114; H01L 29/402

(57) ABSTRACT

A high-voltage semiconductor device is provided. The device includes a semiconductor substrate, a gate dielectric layer, a T-shaped gate, a dielectric neck support, an etch stop feature, a pair of drift regions, and a pair of source/drain regions. The semiconductor substrate has a high-voltage well region. The gate dielectric layer is on the semiconductor substrate. The T-shaped gate is on the gate dielectric layer. The T-shaped gate includes overhangs that extend beyond the neck portion of the T-shaped gate. The dielectric neck support is disposed underneath the overhangs of the T-shaped gate. The etch stop feature is disposed underneath the dielectric neck support. The drift regions are disposed on opposite sides of the T-shaped gate in the high-voltage well region. The source/drain regions are disposed in the pair of drift regions.

### BACKGROUND

### Technical Field

The present disclosure relates to a semiconductor device, and in particular, it relates to a high-voltage semiconductor device having an etch stop feature.

### Description of the Related Art

High-voltage semiconductor technology is applied in integrated circuits (ICs) with high voltages and high power. Herein, the term “high-voltage” refers to a high breakdown voltage (BV). Traditional high-voltage semiconductor devices such as double diffused drain MOSFET (DDDMOSFETs) and lateral diffused MOSFET (LDMOSFET) are mainly used in devices with about 18 volts or higher. The advantages of high-voltage device technology include cost effectiveness and process compatibility, and thus high-voltage device technology has been widely used in display driver IC devices, and power supply devices, and in fields such as power management, communications, autotronics, and industrial control.

Because of the properties of the DDDMOSFET, which include compactness and high output current, it has been widely used in switch regulators. A double diffused drain (DDD) is formed of two implantation/doping regions that serve as a source or a drain in a high-voltage MOSFET device.

When designing a DDDMOSFET, low on-resistance (Ron) and high breakdown voltage (BV) are two main concerns. In DDDMOSFET design, the space between the drain and the channel region may be reduced, thereby reducing the on-resistance, which, however, reduces the breakdown voltage of DDDMOSFET and increases the leakage.

Although existing high-voltage semiconductor devices have been adequate for their intended purposes, they have not been entirely satisfactory in all respects.

### BRIEF SUMMARY OF THE DISCLOSURE

Some embodiments of the disclosure provide a semiconductor device. The semiconductor device includes a semiconductor substrate, a gate dielectric layer, a T-shaped gate, a dielectric neck support, an etch stop feature, a pair of drift regions, and a pair of source/drain regions. The semiconductor substrate has a high-voltage well region. The gate dielectric layer is on the semiconductor substrate. The T-shaped gate is on the gate dielectric layer. The T-shaped gate includes overhangs that extend beyond the neck portion of the T-shaped gate. The dielectric neck support is disposed underneath the overhangs of the T-shaped gate. The etch stop feature is disposed underneath the dielectric neck support. The drift regions are disposed on opposite sides of the T-shaped gate in the high-voltage well region. The source/drain regions are in the pair of drift regions.

Some embodiments of the disclosure provide a method for manufacturing a semiconductor device. The method includes providing a semiconductor substrate having a high-voltage well region. A gate dielectric layer is formed on the semiconductor substrate. A pair of drift regions is formed in the high-voltage well region. An etch stop layer is formed on the gate dielectric layer. A dielectric neck support is formed on the etch stop layer, wherein the etch stop layer serves as an etch stop point when forming the dielectric neck support. A T-shaped gate is formed on the gate dielectric layer, wherein the T-shaped gate includes overhangs that extend beyond the neck portion of the T-shaped gate and on the dielectric neck support. A pair of source/drain regions is formed in the pair of drift regions.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1-3, 4A, 4B, 5, and 6 are cross-sectional views illustrating a method for manufacturing a high-voltage semiconductor device in accordance with an embodiment of the present disclosure.

FIG. 7A is a top view of a high-voltage semiconductor device in accordance with an embodiment of the present disclosure.

FIG. 7B is a top view of a high-voltage semiconductor device in accordance with another embodiment of the present disclosure.

FIGS. 8A and 8B are diagrams illustrating a current-voltage relationship of a drain of a high-voltage semiconductor device in accordance with some embodiments.

### DETAILED DESCRIPTION OF THE DISCLOSURE

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first component over or on a second component in the description that follows may include embodiments in which the first and second components are formed in direct contact, and may also include embodiments in which additional components may be formed between the first and second components, such that the first and second components may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that additional operations can be provided before, during, and after the method, and some of the operations described can be replaced or eliminated for other embodiments of the method.

A high-voltage semiconductor device and a method for manufacturing the same of embodiments of the present disclosure are described in the following description. This description is made for the purpose of illustrating the general principles of the disclosure and should not be taken in a limiting sense. These are, of course, merely examples and are not intended to be limited. A person having ordinary skill in the art will readily understand other modifications that may be made that are contemplated within the scope of other embodiments. Although method embodiments may be described in a particular order, various other method embodiments may be performed in any logical order and may include fewer or more steps than what is described herein.

An exemplary embodiment of the present disclosure provides a high-voltage semiconductor device, such as a DDDMOSFET, which utilizes a dielectric neck support disposed underneath edges of a T-shaped gate to enhance a breakdown voltage of the high-voltage semiconductor device. As a result, when the space between the drain and the channel region and the size of the high-voltage semiconductor device are reduced to improve the on-resistance and reduce the leakage, the breakdown voltage of the high-voltage semiconductor device is not compromised.

Furthermore, in some embodiments, the dielectric neck support is formed by an end point detection etching process (also referred to as an end mode etching process). The dielectric neck support formed by the end mode etching process may control a thickness of the dielectric neck support more efficiently and precisely than the time mode etching process, and thus the process window may be enlarged.

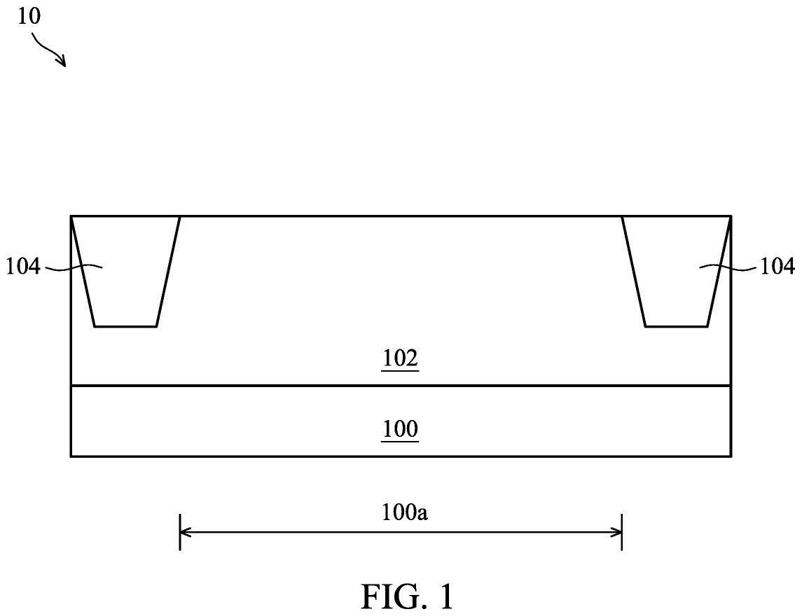

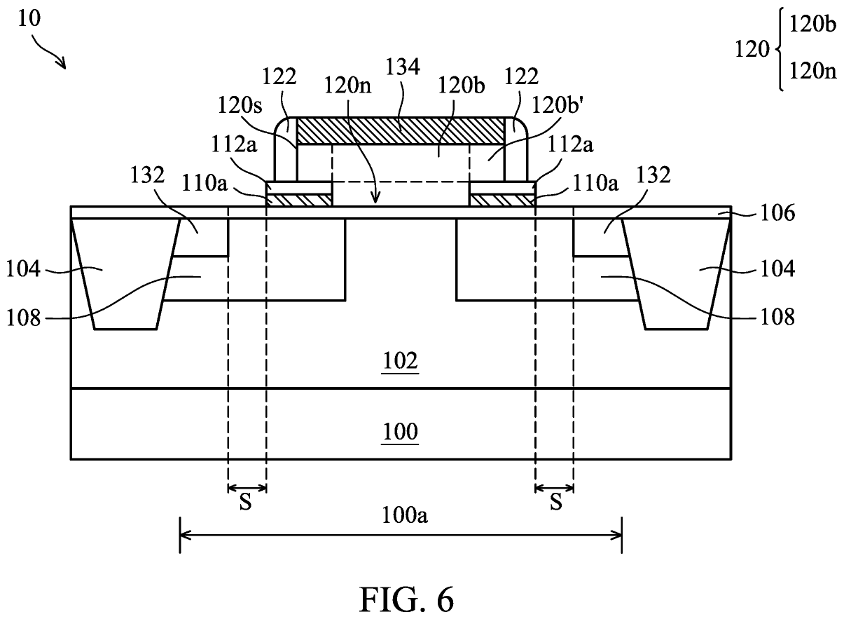

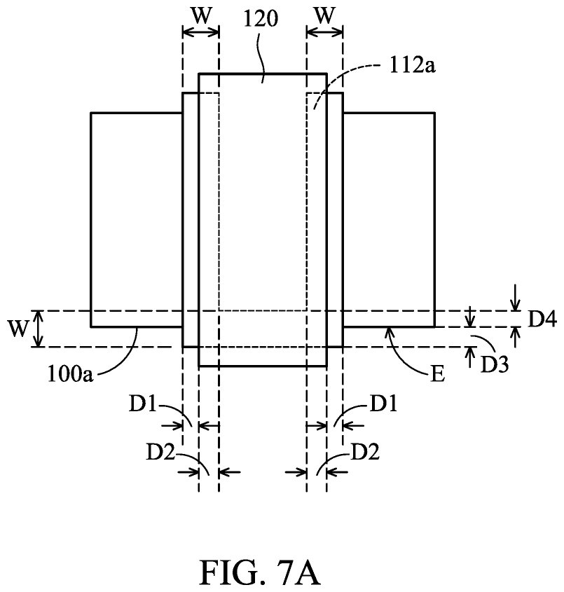

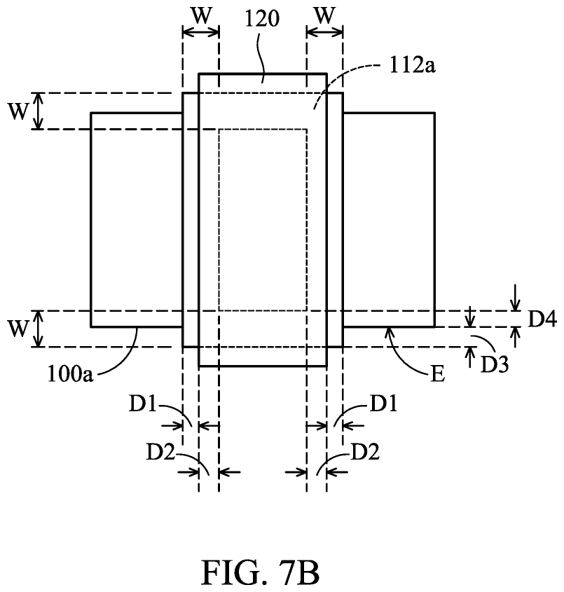

FIGS. 1 to 6 are cross-sectional views illustrating intermediate stages of a process for forming a high-voltage semiconductor device 10 of FIG. 6 in accordance with some embodiments of the present disclosure. FIGS. 7A and 7B are top views of the high-voltage semiconductor device in accordance with different embodiments of the present disclosure. FIGS. 7A and 7B do not illustrate all of the features for the purpose of simplicity and clarity. First referring to FIG. 1, a semiconductor substrate 100 including a high-voltage well region 102 and at least an isolation structure 104 is provided. The isolation structure 104 is used to define an active region 100a in the high-voltage well region 102 of the semiconductor substrate 100, and to electrically isolate a variety of device structures formed in and/or on the semiconductor substrate 100 in the active region 100a. In the embodiment, the semiconductor substrate 100 may be a silicon substrate, a silicon germanium (SiGe) substrate, a compound semiconductor substrate, a bulk semiconductor substrate, a silicon-on-insulator (SOI) substrate or another well-known semiconductor substrate.

In some embodiments, the isolation features 140 include shallow trench isolation (STI) features, local oxidation of silicon (LOCOS) features, other suitable isolation features, or a combination thereof. In some embodiments, the semiconductor substrate 100 may have a first conductivity type, such as a P-type or N-type. Moreover, the high-voltage well region 102 may have the first conductivity type. In one embodiment, the high-voltage well region 102 is P-type and has a doping concentration of about 1.0×10¹⁵ ions/cm³ to about 1.0×10¹⁷ ions/cm³, for example, about 5.0×10¹⁶ ions/cm³. In another embodiment, the high-voltage well region 102 is N-type and has a doping concentration of about 1.0×10¹⁵ ions/cm³ to about 1.0×10¹⁷ ions/cm³, for example, about 6.0×10¹⁶ ions/cm³.

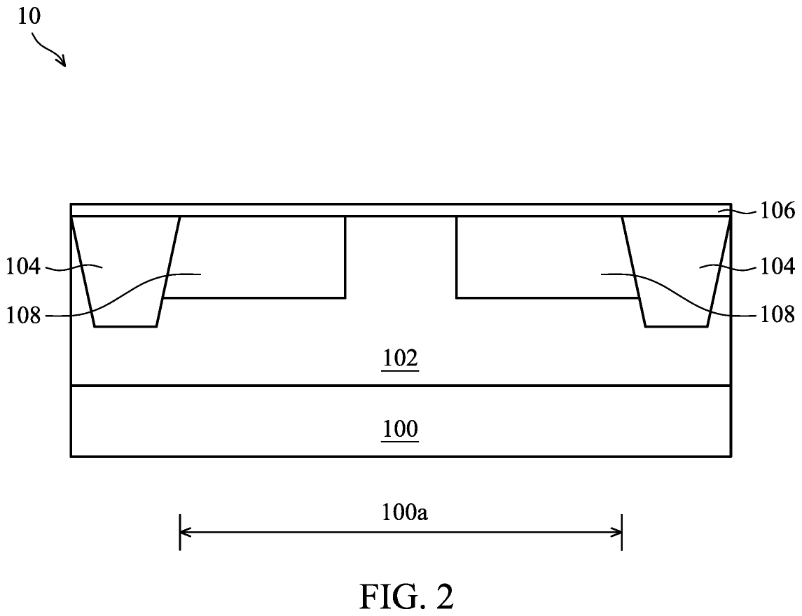

Please refer to FIG. 2, in which a gate dielectric layer 106 is formed on the high-voltage well region 102. In some embodiments, the gate dielectric layer 106 covers the entire active region 100a and extends onto the isolation structures 104. In some embodiments, the gate dielectric layer 106 may include or be silicon oxide, silicon nitride, silicon oxynitride, high-k dielectric material (having a k value greater than about 7.0), any other suitable dielectric material, or a combination thereof. For example, the gate dielectric layer 106 may include silicon dioxide. In one embodiment, a thickness of the gate dielectric layer 106 may be in a range of about 300 Å to 500 Å. The gate dielectric layer 106 may be formed by a thermal oxidation process, chemical vapor deposition (CVD), physical vapor deposition (PVD), atomic layer deposition (ALD) or another suitable process.

Next, still referring to FIG. 2, a pair of drift regions 108 is formed in the high-voltage well region 102 corresponding to the active region 100a. In one embodiment, the depth of the drift doping regions 108 is less than that of the isolation structure 104. The drift doping regions 108 have a second conductivity type that is different from the first conductivity type. In one embodiment, the first conductivity type is P-type and the second conductivity type is N-type. In another embodiment, the first conductivity type is N-type and the second conductivity type is P-type. An implantation mask (not shown) may be formed over the high-voltage well region 102 by a lithography process. Thereafter, an ion implantation process may be performed, so as to form the drift doping regions 108, and a channel region (not shown) is defined between the drift doping regions 108. Moreover, an annealing process, such as a rapid thermal annealing (RTA) process, may be performed on the drift doping regions 108 after forming the drift doping regions 108, and the duration of the annealing process is about 5 seconds to about 20 seconds, for example, about 10 seconds.

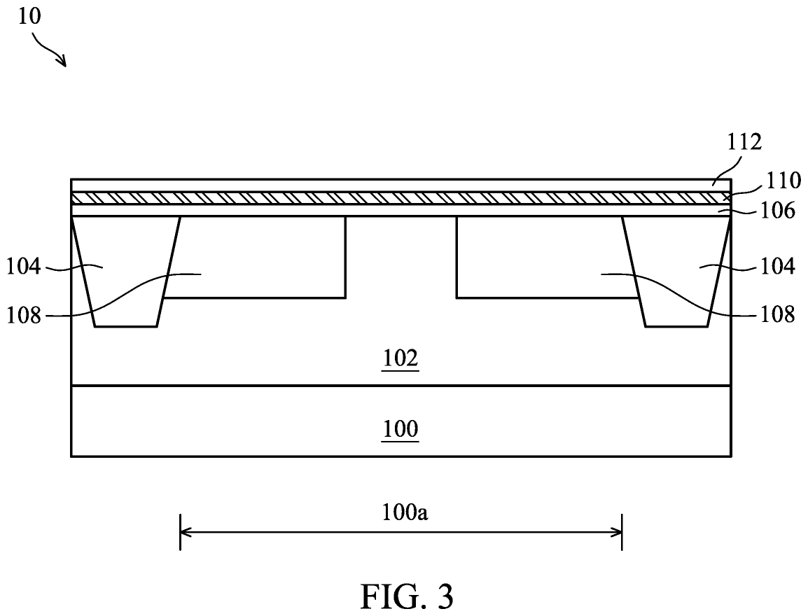

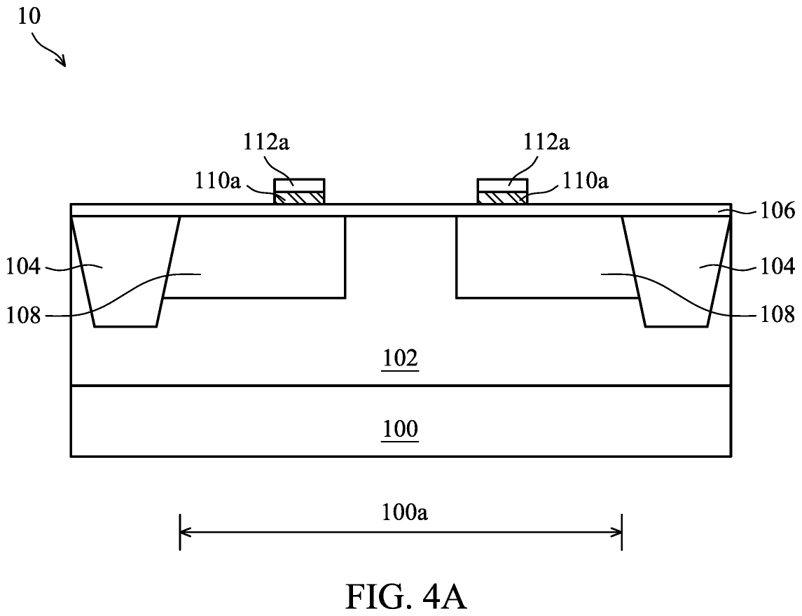

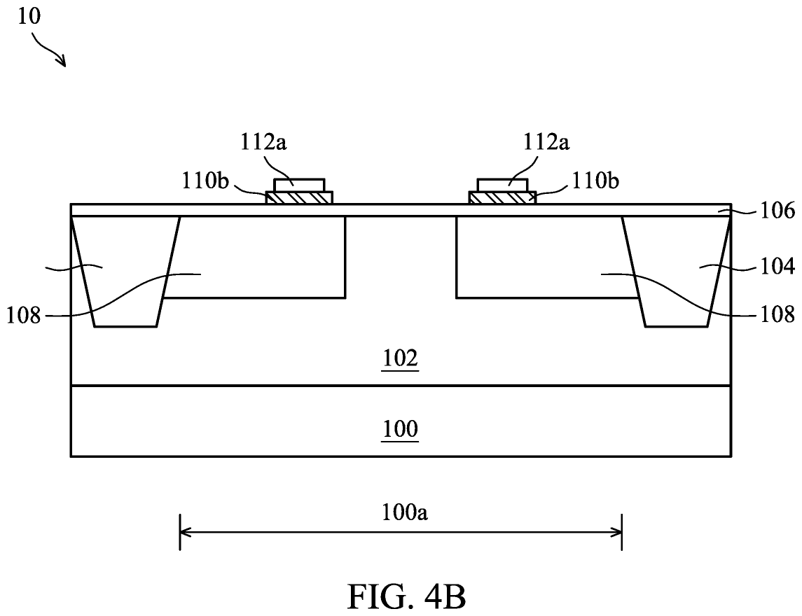

Please refer to FIG. 3, in which an etch stop layer 110 is formed to cover the gate dielectric layer 106, and a dielectric support layer 112 (also referred to as a dielectric layer 112) is formed on the etch stop layer 110. The etch stop layer 110 and the dielectric support 112 will be formed into an etch stop feature 110a and a dielectric neck support 112a (not illustrated in FIG. 3 but illustrated and described below with respect to FIG. 4A-4B) in the subsequent processes respectively.

When performing the etching process, the etch stop layer 110 may serve as an end point to provide a mechanism for stopping an etching process, which is referred to as an end point detection. The dielectric neck support formed by the end mode etching process may control the thickness of the dielectric neck support more efficiently and precisely than the time mode etching process, and thus the process window may be enlarged. The etch stop layer 110 may be formed of a material having a different etch selectivity from adjacent layers or components (i.e., the dielectric layer 112 and/or the gate dielectric layer 106). In some embodiments, the etch stop layer 110 may include or be dielectric material, such as nitrogen-contained material, silicon-contained material, and/or carbon-contained material. For example, the etch stop layer 110 may include or be silicon nitride, silicon carbon nitride, carbon nitride, silicon oxynitride, silicon carbon oxide, the like, or a combination thereof.

In another embodiments, the etch stop layer 110 may include or be a conductive material or a semiconductor material, such as polysilicon. The etch stop feature 110a including conductive materials or semiconductor materials can function as a field plate after the etch stop layer 110 is formed into the etch stop feature 110a. The field plate may rebuild the electric field intensity distribution of the channel, which may decrease the peak value of the electric field of the gate (near to the drain terminal) so as to increase the breakdown voltage. The etch stop layer 110 may be formed by a deposition process, plating, and/or another suitable method. For example, the deposition process may be a chemical vapor deposition (CVD), a physical vapor deposition (PVD) (such as sputtering), an atomic layer deposition (ALD), and/or another deposition process.

In some embodiments, the dielectric layer 112 may include the same material as that of the gate dielectric layer 106, such as silicon dioxide. In other embodiments, the dielectric layer 112 may include a different material than the gate dielectric layer 106. For example, the gate dielectric layer 106 may include silicon dioxide and the dielectric layer 112 may include silicon nitride, silicon oxynitride or another high dielectric constant dielectric material (e.g., HfO₂, ZrO₂, Al₂O₃, TiO₂, and the like). The dielectric layer 112 may be formed by a deposition process, such as a chemical vapor deposition (CVD), a physical vapor deposition (PVD), or another deposition process. In a specific embodiment, the gate dielectric layer 106 is silicon dioxide. In a specific embodiment, the etch stop layer 110 is silicon nitride. In another specific embodiment, the etch stop layer 110 is polysilicon.

Please refer to FIG. 4A, in which the etch stop layer 110 and the dielectric layer 112 are formed into the etch stop feature 110a and the dielectric neck support 112a respectively by a lithography process and an etching process. Generally, the lithography process includes depositing a photoresist material (not shown), exposing, and developing to remove a portion of the photoresist material. The remaining portions of photoresist material protect underlying materials (for example, the dielectric layer 112 and the etch stop layer 110) from subsequent processes (for example, an etching process). In some embodiments, a photoresist (not shown) is formed to cover the dielectric layer 112, and patterned by exposing the photoresist to light using an appropriate photomask. Exposed or unexposed portions of the photoresist may then be removed depending on whether a positive or negative resist is used. Next, the patterned photoresist may be used to etch the dielectric layer 112 and the etch stop layer 110, so as to form the etch stop feature 110a and the dielectric neck support 112a respectively. The dielectric neck support 112a can reduce the electric field beneath the edge of the gate (will be formed in the subsequent processes) and the gate-drain capacitance (Cgd), so as to increase the breakdown voltage of the high-voltage semiconductor device and enhance the switching characteristic of the high-voltage semiconductor device. Moreover, the method of forming the dielectric neck support 112a by etching the dielectric layer 112 using the etch stop layer 110 as an etch end point (i.e., the end point mode etching process) has some advantages, for example, the dielectric neck support 112a formed by the end mode etching process may control the thickness of the dielectric neck support 112a more efficiently and precisely than the time mode etching process, and thus the process window may be enlarged. In some embodiments, the etch stop feature 110a including conductive materials or semiconductor materials can function as a field plate to further increase the breakdown voltage of the high-voltage semiconductor device.

In one embodiment, a thickness of the dielectric neck support 112a is in a range of about 500 Å to 700 Å. In one embodiment, a thickness of the etch stop feature 110a is in a range of about 300 Å to 500 Å. The etching process may be a dry etching process or a wet etching process, such as reactive ion etch (RIE), neutral beam etch (NBE), the like, or a combination thereof. The etching may be anisotropic. In one embodiment, the dielectric neck support 112a has a U-shaped contour as viewed from a top-view aspect (as shown in FIG. 7A) and has a width W. In another embodiment, the dielectric neck support 112a has a loop-shaped contour as viewed from a top-view aspect (as shown in FIG. 7B). Furthermore, in some embodiments, as shown in FIG. 4A, the etch stop feature 110a and the dielectric neck support 112a may have the same size. For example, the etch stop feature 110a and the dielectric neck support 112a may be formed simultaneously in a single etching step. In another embodiment, as shown in FIG. 4B, the etch stop feature 110a and the dielectric neck support 112a may have different sizes. For example, an additional patterned photo resist formed by an additional lithography process may be used to form the etch stop feature 110a and the dielectric neck support 112a in two different etching steps respectively.

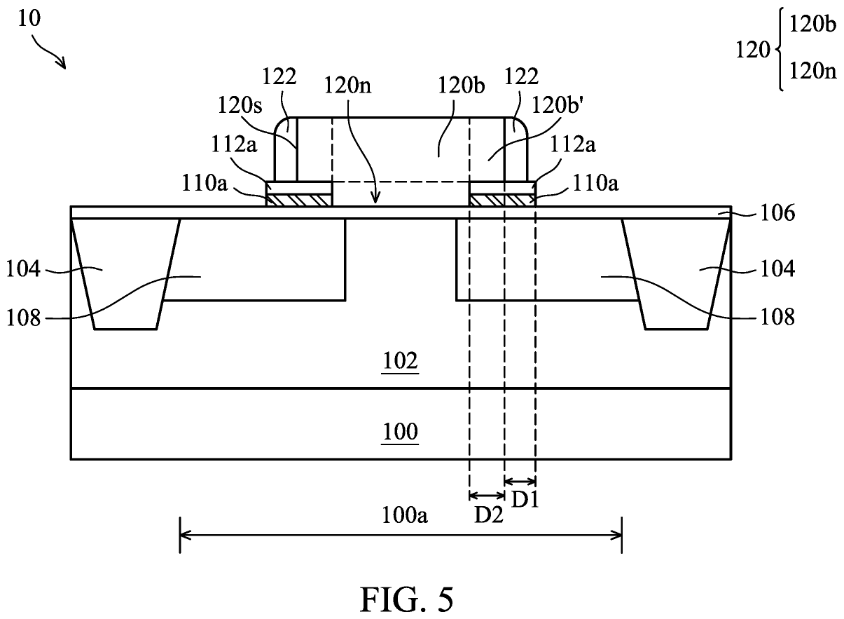

Please refer to FIG. 5, in which a T-shaped gate 120 is formed in the gate dielectric layer 106. Next, a sidewall spacer 122 is formed on opposite sidewalls of the T-shaped gate 120. The T-shaped gate 120 includes a bar portion 120b and a neck portion 120n, wherein a portion of the bar portion 120b extending beyond the neck portion 120n is an overhang 120b′. In one embodiment, as shown in FIGS. 7A and 7B, the dielectric neck support 112a with a U-shaped or loop-shaped contour as viewed from a top-view aspect protrudes from the sidewall 120s of the T-shaped gate 120 by a first distance D1, and the first distance D1 is greater than a width of the sidewall spacer 122. Moreover, the dielectric neck support 112a extends beneath the T-shaped gate 120 from the sidewall 120s of the T-shaped gate 120 by a second distance D2 (i.e., the width of the overhang 120b′) that is greater than the first distance D1. As a result, the electric field beneath the edge of the T-shaped gate 120 and the gate-drain capacitance (Cgd) can be reduced by the dielectric neck support 112a with a U-shaped or loop-shaped contour as viewed from a top-view aspect. Furthermore, as viewed from a top-view aspect, a portion of the dielectric neck support 112a perpendicular to the T-shaped gate 120 protrudes outwardly from an edge E of the active region 100a by a third distance D3. Moreover, the dielectric neck support 112a extends from the edge E of the active region 100a toward the active region 100a by a fourth distance D4 that is less than the third distance D3.

In some embodiments, the T-shaped gate 120 includes polysilicon, metal material, metal silicide, another suitable conductive material or a combination thereof. The T-shape gate 120 may be formed by an appropriate deposition process (for example, chemical vapor deposition, physical vapor deposition, metal-organic chemical vapor deposition (MOCVD)) and/or silicidation process, lithography process and etching process (for example, dry etching process or wet etching process). The sidewall spacer 122 includes a material that is different from the material used for the T-shaped gate 120. In some embodiments, the sidewall spacer 122 includes dielectric material, such as silicon nitride or silicon oxynitride. In one embodiment, after forming the T-shaped gate 120, one or more layers (not shown) are formed by conformally depositing dielectric materials on the high-voltage semiconductor device 10. Next, an anisotropic etching process is performed to remove portions of the one or more layers, so as to form the sidewall spacer 122.

Please refer to FIG. 6, in which a pair of source/drain regions 132 with the first conductivity type is formed in the corresponding drift regions 108, and a top doping region 134 is formed in a top portion of the T-shaped gate 120 simultaneously. In one embodiment, the source/drain regions 132 have a doping concentration greater than that of the drift regions 110 serving as a double diffused drain. Furthermore, the source/drain regions 132 and the top doping region 134 have the same conductivity type and the same doping concentration. In one embodiment, the source/drain regions 132 may be laterally separated from the sidewall spacer 122 by a spacing S (Namely, the source/drain regions 132 are not self-aligned to the gate spacers 130) to decrease the leakage of the high-voltage semiconductor device 10. The spacing S is in a range of about 0.15 um to 0.30 um. Moreover, the top doping region 134 may reduce the contact resistance of the T-shaped gate 120.

An implantation mask (not shown) is formed over the high-voltage well region 120 by a lithography process. Then, an ion implantation process may be performed to form the source/drain regions 132, and to form a top doping region 134 in the top portion of the T-shaped gate 120. After forming the source/drain regions 132, a metallization layer (not shown) may be formed over the structure shown in FIG. 6 by a well-known metallization process. As a result, a high-voltage semiconductor device 10 is completed. In one embodiment, the metallization layer may include an interlayer dielectric (ILD) layer and an interconnect structure in the ILD layer. In one embodiment, the interconnect structure at least includes metal electrodes that are coupled to the source/drain regions 132 and top doping region 134.

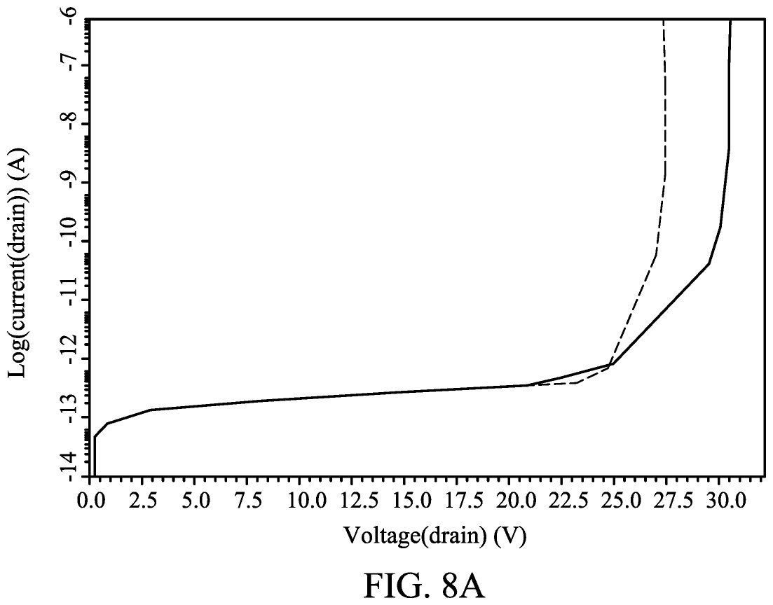

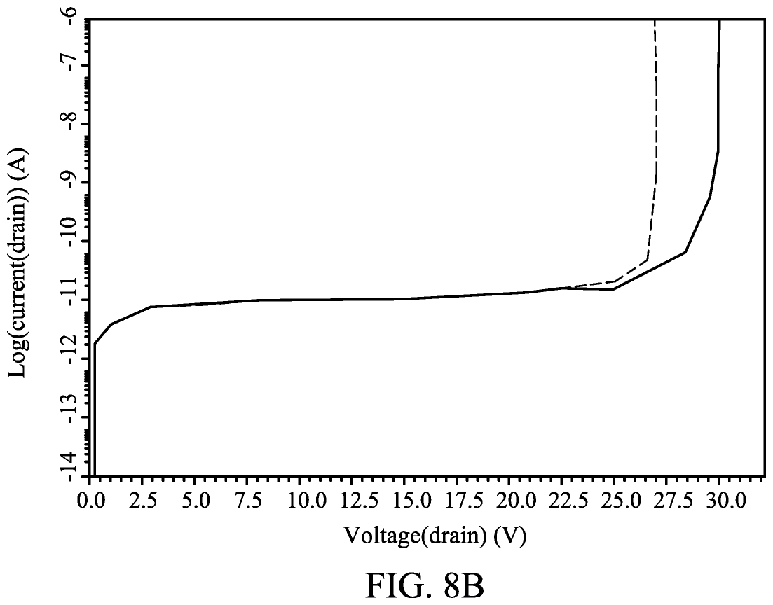

FIGS. 8A and 8B are diagrams illustrating a current-voltage relationship of a drain of a double diffused drain MOSFET having an n-type/p-type high-voltage well respectively in accordance with some embodiments. The dashed line represents a double diffused drain MOSFET with no field plate, that is, the embodiment where the etch stop feature is dielectric material (for example, silicon nitride). The solid line represents a double diffused drain MOSFET with a field plate, that is, the embodiment where the etch stop feature is conductive material or semiconductor material (for example, polysilicon). As shown in FIGS. 8A and 8B, regardless of whether the double diffused drain MOSFET has an n-type or p-type high-voltage well, the double diffused drain MOSFET with a field plate has a higher breakdown voltage than the double diffused drain MOSFET with no field plate.

Please refer to FIG. 6, in the embodiment of the present disclosure, the high-voltage semiconductor device 10 includes a high-voltage well region 102 and at least an isolation structure 104. The isolation structure 104 defines an active region 100a in the high-voltage well region 102 of the semiconductor substrate 100.

In this embodiment, the high-voltage semiconductor device 10 further includes the gate dielectric layer 106 over the semiconductor 100, and the T-shaped gate 120 on the gate dielectric layer 106. In one embodiment, the gate dielectric layer 106 covers the entire active region 100a and extends onto the isolation structure 104. In a specific embodiment, the gate dielectric layer 106 may include silicon dioxide. The T-shaped gate 120 includes a bar portion 120b and a neck portion 120n, wherein a portion of the bar portion 120b extending beyond the neck portion 120n is an overhang 120b′, as shown in FIG. 6. In one embodiment, the T-shaped gate 120 may include polysilicon. In one embodiment, the T-shaped gate 120 has the top doping region 134 to reduce the contact resistance of the T-shaped gate 120.

In this embodiment, the high-voltage semiconductor device 10 further includes the dielectric neck support 112a disposed underneath the overhangs 120b′ of the T-shaped gate 120, wherein the dielectric neck support 112a extends beyond edges of the overhangs 120b′. The dielectric neck support 112a is over the high-voltage well region 102. The dielectric neck support 112a is a patterned dielectric layer, and the dielectric neck support 112a does not cover the entire active region 100a and extend onto the isolation structure 104. As shown in FIGS. 7A and 7B, the dielectric neck support 112a at least partially surrounds the T-shaped gate 120. In some embodiments, the dielectric neck support 112a has a U-shaped contour as viewed from the top-view aspect. In other embodiments, the dielectric neck support 112a has a loop-shaped contour as viewed from the top-view aspect. In one embodiment, the dielectric layer 112 may include the same material as that of the gate dielectric layer 106, such as silicon dioxide. In another embodiment, the dielectric layer 112 may include a different material than the gate dielectric layer 106.

In this embodiment, the high-voltage semiconductor device 10 further includes the etch stop feature 110a disposed underneath the dielectric neck support 112a. In some embodiments, the etch stop feature 110a and the dielectric neck support 112a have the same size. In other embodiments, the width of the etch stop feature 110a is greater than the width of the dielectric neck support 112a. In some embodiments, the etch stop feature 110a includes a conductive material or a semiconductor material to serve as a field plate. In a specific embodiment, the etch stop feature 110a is polysilicon.

In this embodiment, the high-voltage semiconductor device 10 further includes the pair of drift regions 108 disposed on opposite sides of the T-shaped gate 120 in the high-voltage well region 102, and the pair of source/drain regions 132 in the pair of drift regions 108.

In this embodiment, the high-voltage semiconductor device 10 further includes the sidewall spacer 122. The sidewall spacer 122 covers the dielectric neck support 112a and extends along sidewalls of the overhangs 120b′ of the T-shaped gate 120, wherein the width of the dielectric neck support 112a is greater than the width of the sidewall spacer 122. In one embodiment, the sidewall spacer 122 is laterally spaced apart from the source/drain regions 132 by a spacing S.

In accordance with the above embodiments, during the process for forming the high-voltage semiconductor device with U-shape or loop-shape dielectric layer, using the etch stop layer as an etch end point (i.e., the end point mode etching process) has some advantages. For example, the dielectric neck support formed by the end mode etching process may be able to control a thickness of the dielectric neck support more efficiently and precisely than the time mode etching process, thereby enlarging the process window. Moreover, the etch stop feature comprising conductive materials or semiconductor materials can function as a field plate to further increase the breakdown voltage of the high-voltage semiconductor device. As a result, in the high-voltage semiconductor device design, the source/drain region can be laterally separated from the sidewall spacer by a space, thereby reducing the leakage of the high-voltage semiconductor device. Moreover, the on-resistance of the high-voltage semiconductor device can be reduced by reducing the plane size of the high-voltage semiconductor device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a semiconductor substrate having a high-voltage well region;
a gate dielectric layer on the semiconductor substrate;
a T-shaped gate on the gate dielectric layer, wherein the T-shaped gate comprises a bar portion and a neck portion, wherein the bar portion comprises overhangs that extend beyond the neck portion of the T-shaped gate, and the bar portion and the neck portion are made of the same material;
a dielectric neck support disposed underneath the overhangs of the T-shaped gate;
an etch stop feature disposed underneath the dielectric neck support, wherein the dielectric neck support and the etch stop feature directly contact sidewalls of the neck portion of the T-shape gate;
a pair of drift regions disposed on opposite sides of the T-shaped gate in the high-voltage well region; and
a pair of source/drain regions in the pair of drift regions.

2. The semiconductor device of claim 1, further comprising a sidewall spacer covering the dielectric neck support and extending along sidewalls of the overhangs of the T-shaped gate.

3. The semiconductor device of claim 2, wherein the sidewall spacer is laterally spaced apart from the source/drain regions.

4. The semiconductor device of claim 2, wherein a width of the dielectric neck support is greater than a width of the sidewall spacer and the sidewall spacer does not extend beyond the dielectric neck support.

5. The semiconductor device of claim 1, wherein in a top-view, the dielectric neck support at least partially surrounds the T-shaped gate.

6. The semiconductor device of claim 5, wherein the dielectric neck support has a U-shaped or a loop-shaped contour as viewed from the top-view aspect.

7. (canceled)

8. The semiconductor device of claim 1, wherein the dielectric neck support extends beyond edges of the overhangs.

9. The semiconductor device of claim 1, wherein a width of the etch stop feature is greater than a width of the dielectric neck support.

10. The semiconductor device of claim 1, wherein the etch stop feature comprises a conductive material or a semiconductor material to serve as a field plate.

11. The semiconductor device of claim 1, wherein the etch stop feature is polysilicon.

12. A method for manufacturing a semiconductor device, comprising:
providing a semiconductor substrate having a high-voltage well region;
forming a gate dielectric layer on the semiconductor substrate;
forming a pair of drift regions in the high-voltage well region;
forming an etch stop layer on the gate dielectric layer;
forming a dielectric neck support on the etch stop layer, wherein the etch stop layer serves as an etch stop point when forming the dielectric neck support;
forming a T-shaped gate on the gate dielectric layer, wherein the T-shaped gate comprises overhangs that extend beyond a neck portion of the T-shaped gate and on the dielectric neck support; and
forming a pair of source/drain regions in the pair of drift regions.

13. The method of claim 12, further comprising forming a sidewall spacer covering the dielectric neck support and extending along sidewalls of the overhangs of the T-shaped gate.

14. The method of claim 13, wherein a width of the dielectric neck support is greater than a width of the sidewall spacer.

15. The method of claim 12, wherein in a top-view, the dielectric neck support at least partially surrounds the T-shaped gate.

16. The method of claim 12, wherein the dielectric neck support extends beyond edges of the overhangs.

17. The method of claim 12, wherein a width of the etch stop layer is greater than a width of the dielectric neck support.

18. The method of claim 12, wherein the etch stop layer comprises a conductive material or a semiconductor material to serve as a field plate.

19. The method of claim 18, wherein the etch stop layer is polysilicon.

20. The method of claim 12, wherein the T-shaped gate has a top doping region, wherein the top doping region has the same conductivity type and the same doping concentration as those of the source/drain region.

21. The semiconductor device of claim 1, further comprising a top doping region in a top portion of the T-shaped gate.
